(19) United States
(12) Patent Application Publication
(10) Pub. No.: US 2010/0230786 A1
(43) Pub. Date: Sep. 16, 2010

(54) PRODUCTION OF INTEGRATED CIRCUITS COMPRISING SEMICONDUCTOR INCOMPATIBLE MATERIALS

(75) Inventor: Wolfgang Schnitt, Norderstedt (DE)

Correspondence Address: NXP, B.V.;NXP INTELLECTUAL PROPERTY & LICENSING, M/S41-SJ, 1109 MCKAY DRIVE, SAN JOSE, CA, 95131, US

(73) Assignee: NXP B.V., Eindhoven (NL)

(21) Appl. No.: 12/161,707

(22) PCT Filed: Jan. 25, 2007
(86) PCT No.: PCT/IB07/50262

§ 371 Date: Jul. 22, 2008

(30) Foreign Application Priority Data
Jan. 26, 2006 (EP) 06100871.0

(51) Int. Cl. H01L 29/92; H01L 21/02; H01L 23/28

(52) U.S. Cl. 257/532; 438/3; 257/787; 257/E21.008; 257/E23.116; 257/E29.342

(57) ABSTRACT

It is described a procedure for the integration of semiconductor incompatible materials in a process family created for the production of passive electric components and active electric components formed within integrated circuits. The procedure is applicable in known techniques like bipolar, MOS or BIMOS processes for semiconductor production. The modular concept of the described procedure may combine diodes, resistors and capacitors, which components are made from different materials. The provision of an encapsulation material for a semiconductor incompatible material enables the manufacturing of integrated circuits even within a sensitive environment with respect to contaminations originating from the semiconductor incompatible material. The encapsulation is provided early within the manufacturing process such that the risk for a contamination may be reduced to a minimum. Further, it is described an integrated circuit element and an integrated circuit comprising an encapsulated semiconductor incompatible material. The semiconductor incompatible material may be a lead containing ceramics, in particular Lead Lanthanum Zirconium Titanate (PLZT), which is used for ferroelectric capacitors and which represents a highly contaminating substance in particular for ‘heavy metal sensitive’ environments.

The present invention relates to the field of manufacturing integrated circuits. In particular the present invention relates to the field of manufacturing integrated circuits comprising electronic components, which are formed with a semiconductor incompatible material. Such a material is a material representing a potential contamination source for other process steps for forming a semiconductor component on the integrated circuit. The present invention further relates to circuit elements and to circuits, which may be produced with the above mentioned production methods.

In order to produce reliable integrated electronic circuits comprising e.g. ferroelectric capacitors, it is well known to encapsulate a ferroelectric material in order to avoid a deteriorating of the ferroelectric material in the coarse of a life cycle of a electronic product comprising the ferroelectric capacitor.

The document U.S. Pat. No. 6,344,363 B1 discloses a method for forming a ferroelectric film on a principal surface of an underlying substrate. By a vapor deposition using high density plasma, an insulating protection film is deposited so that the ferroelectric film is covered therewith. The deposited protection film can prevent the ferroelectric film from deteriorating.

The document US 2005/0205906 A1 discloses a method for protecting ferroelectric capacitors from hydrogen diffusion in semiconductor devices. Therefore, nitrided aluminium oxide is formed over a ferroelectric capacitor, and one or more silicon nitride layers are formed over the nitrided aluminium oxide. Hydrogen barriers are also provided in which an aluminium oxide is formed over the ferroelectric capacitors, with two or more silicon nitride layers formed over the aluminium oxide, wherein the second silicon nitride layer comprises a low silicon-hydrogen SiN material.

There may be a need for an improved manufacturing method for forming ferroelectric capacitors on an integrated circuit.

This need may be met by a method for producing an integrated circuit element as set forth in claim 1. According to a first aspect of the invention an integrated circuit element is produced, which comprises both semiconductor electric components and non-semiconductor electric components. The production method comprises the steps of (a) forming a layer of a semiconductor incompatible material on a substrate, (b) encapsulating the semiconductor incompatible material with an encapsulating material, and (c) further processing the integrated circuit, wherein contact electrodes are formed in order to contact a component comprising the semiconductor incompatible material.

In this context a semiconductor incompatible material is a material, which represents a possible contamination source for a semiconductor forming process, by means of which semiconductor components, e.g. diodes, transistors etc., are formed on the substrate.

The material incompatible for semiconductors can be formed directly or indirectly on the substrate. In this context an indirect formation means that in between the substrate and the semiconductor incompatible material there is provided an intermediate layer.

The encapsulation may eliminate any contamination of other parts of the integrated circuit, which contaminations arise from the semiconductor incompatible material. In order to provide for a maximum reliability of the integrated circuit production process the encapsulation should be carried out as early as possible in order to reduce the risk of contaminating other parts or components of the integrated circuit.

A close encapsulation of the semiconductor incompatible material may provide the possibility that new types of materials may by used for future semiconductor manufacturing processes. Therefore, it may be possible to use materials which, according to the state of the art, are not allowed because the probability for an unwanted contamination of the process environment is to high.

An early encapsulation of the semiconductor incompatible material has the advantage, that process equipment, which gets in contact with the semiconductor incompatible material, may be restricted to a few apparatuses only. Therefore, the described method is compatible to and may be applied to well known processes for manufacturing Bipolar, Bipolar Metal Oxide Semiconductor (BiMOS) and Metal Oxide Semiconductor (MOS) integrated circuits. This provides the advantage, that the described production method may be used without big modifications with respect to known production methods.

A further advantage of the described production method is the possibility that the method may be carried out in different locations i.e. in different semiconductor factories. Therefore, the production of integrated circuits may be carried out in a very flexible way by optionally producing the integrated circuit elements in different factories such that a high factory utilization and, as a consequence, a high production efficiency may be achieved.

According to an embodiment of the invention as set forth in claim 2, the step of forming a layer of a semiconductor incompatible material on a substrate comprises the steps of (b1) forming a first metal layer on the substrate and (b2) forming the semiconductor incompatible material on the first metal layer. Since the semiconductor incompatible material is formed on the first metal layer the encapsulating encloses both the semiconductor incompatible material and the first metal layer. This may provide the advantage that a lower contact or a lower electrode for the semiconductor incompatible material may be provided. Preferably, the first metal layer may be made from platinum or from aluminium.

According to a further embodiment of the invention as set forth in claim 3, the step of forming a layer of a semiconductor incompatible material on a substrate further comprises the step of (b3) forming a second metal layer on top of the semiconductor incompatible material. In other words, the formation of the second layer on top of the semiconductor incompatible material is carried out before accomplishing the step of encapsulating the semiconductor incompatible material. This means, that also the second metal layer is encapsulated together with the first metal layer and with the semiconductor incompatible material.

The encapsulation of also the second metal layer may provide the advantage that an upper contact or an upper electrode for the semiconductor incompatible material may be provided. Preferably, also the second metal layer may be made from platinum or from aluminium.

According to a further embodiment of the invention as set forth in claim 4, the method comprises a further step wherein the semiconductor incompatible material is partially removed such that at least one isolated island remains on the substrate. In principle, each individual island can be used for building up one component comprising the semiconductor incompatible material. Due to the encapsulation the process of forming other components from semiconductor material is not affected. This holds in particular if the encapsulations represent a close barrier for particles originating from the semiconductor incompatible material.

Depending on the type of integrated circuit the removal can be carried out with the semiconductor incompatible material alone, with the semiconductor incompatible material together with the second metal layer or with the semiconductor incompatible material together with both metal layers.

In this context it has to be noted that the partial removal can be accomplished not only with a single step. The removal can rather be carried out with two or more single steps such that e.g. the second metal layer, the semiconductor incompatible material and the first metal layer may be removed individually.

According to a further embodiment of the invention as set forth in claim 5, the at least one isolated island of semiconductor incompatible material is located on the first metal layer, wherein the isolated island covers an area which is at least slightly smaller than the underlying area of the first metal layer and wherein the isolated island is located within a two-dimensional region defined by the lateral edges of the first metal layer. In other words, there is a full overlap between the semiconductor incompatible material and the first metal layer. This may provide the advantage that breaks and cracks may be avoided, which might occur due to different thermal expansion coefficients of the metal and the semiconductor incompatible material. The reason for this is the fact that such breaks and cracks preferably occur at the edges of the metal layer when, in a top view of the integrated circuit, an edge of the semiconductor incompatible material coincides with an edge of the metal layer.

According to a further embodiment of the invention as set forth in claim 6, the encapsulating material is a protection film, in particular the encapsulating material is a nitride film. Depending on the type of material a thin film is sufficient in order to provide for a close encapsulation. This may provide for the advantage that the integrated circuit may be build up within a compact circuit design such that requirements concerning the miniaturisation of modern electronic products may be fulfilled.

According to a further embodiment of the invention as set forth in claim 7, the method comprises a further step wherein the protection film is removed partially. This has the advantage that junction areas which may be formed e.g. on metal conductor paths, on stannous pads and/or on p- or n-doped semiconductor layers may be uncovered such that a further processing of the integrated circuit can be carried out using known techniques for structuring semiconductor circuit devices. In order to provide for the possibility to electrically contact a portion of the second metal layer, which is located above the semiconductor incompatible material, a recess should be formed which provides an opening only to the second metal layer and not to the lateral edges of the semiconductor incompatible material. Thereby, it is possible to electrically contact a component which comprises the semiconductor incompatible material. Due to a close encapsulating barrier this component may be present in an integrated circuit element comprising both a semiconductor and/or a non-semiconductor component, which is made from the semiconductor incompatible material.

In case the encapsulating material is a nitride film the removal can be accomplished effectively by applying a plasma-etch procedure. In particular, the plasma-etch procedure may be carried out using a so-called Contact Opening mask.

According to a further embodiment of the invention as set forth in claim 8, the integrated circuit includes a capacitor, which is build up from the semiconductor incompatible material located between the first metal layer and the second metal layer. This means that the configuration of the capacitor shows a sandwich like structure. This allows for a production of integrated circuits comprising capacitors, which have a precisely defined capacitance. Therefore, a high precision integrated circuit comprising at least one sandwich like capacitor may be build up in an effective way.

According to a further embodiment of the invention as set forth in claim 9, the capacitor is a ferroelectric capacitor. A ferroelectric capacitor is a component comprising a spontaneous polarization. The orientation of the polarization can be changed under the influence of an electric field. With a ferroelectric capacitor new types of microelectronic circuits may be provided. As an example of a very interesting new type of microelectronic circuits Ferroelectric Random Access Memories (FRAM) have to be mentioned, which may be used in computer products as non-volatile memories.

According to a further embodiment of the invention as set forth in claim 10, the semiconductor incompatible material is a lead containing ceramics, in particular the semiconductor incompatible material is Lead Lanthanum Zirconium Titanate (PLZT). These kinds of materials exhibit a strong spontaneous polarization. Therefore, these materials are the preferred dielectric materials for being employed in ferroelectric components. Since in particular heavy metal lead atoms represents a very strong contamination material for semiconductor processes, the described method provides an effective manufacturing of integrated circuits comprising both a lead containing ceramics and a semiconductor material. Therefore, the close encapsulation of the contaminating material allows for a production process for integrated circuits, which process comprises a high reliability.

In order to provide for stable metal layers, which represent electrode plates of the capacitor, the metal layers are preferably made from platinum. However, it will be appreciated that also other metals may be used in order to provide stable capacitor plates.

Preferably the PLZT layer does not cover the whole substrate, such that edges of the substrate are not covered with the semiconductor incompatible material. This provides the advantage that the probability for a peel off of the semiconductor incompatible material from the substrate is reduced. The reason for this is the fact, that a peel off is more likely when the substrate and the semiconductor incompatible material comprise a common edge.

According to a further embodiment of the invention as set forth in claim 11 the capacitor represents a symmetric assembly, wherein one type of dielectric layer is inserted between the first metal layer and the second metal layer. Forming the capacitor in a symmetric way with respect to the dielectric/ferroelectric layer provides the advantage that the capacitance of the capacitor is not affected by the sign of the applied voltage. In other words, the capacitance for a positive voltage is the same as the capacitance for a negative voltage of the same magnitude.

Furthermore, the expected life cycle for a symmetric formed capacitor is longer than the life cycle for an asymmetric formed capacitor, wherein a dielectric layer is provided between two electrodes made from different materials. As an example for such an asymmetric capacitor a ferroelectric capacitor is mentioned herewith, wherein a PLZT layer is provided between a first electrode made from platinum and a second electrode made from Titan Tungsten Nitride (TiWN). The extension of the estimated life cycle is in particular significant, if negative voltages are applied to the capacitor, which voltages have a level of more than 8 V.

The avoidance of TiWN as an electrode material of the capacitor provides a further advantage. Since TiWN is also used as a material for forming an electric resistance it is possible that during a structuring process of a TiWN film also an undercoating layer may be damaged, which undercoating layer is formed under a metal layer in order to provide for a reliable contact of the capacitor. The metal layer for connecting the capacitor is usually formed from platinum. Such a damaging is not unlikely since also undercoating layers are typically made from Titan. A damaging of the undercoating layer leads to a reduced adhesion between the undercoating layer and the metal layer such that the corresponding capacitors may peel off.

The above-mentioned need may further be met by an integrated circuit element as set forth in claim 12. According to a second aspect of the invention an integrated circuit element is provided. In particular, the integrated circuit element may be manufactured with a method according to any one of the above-mentioned claims. The integrated circuit element comprises a substrate, a semiconductor incompatible material formed on the substrate and an encapsulating material encapsulating the semiconductor incompatible material.

The encapsulating material ensures that a contamination of semiconductor material of the integrated circuit element may by avoided during the manufacturing process of the integrated circuit element.

According to a further embodiment of the invention as set forth in claim 13, a first metal layer is directly formed on the lower surface of the semiconductor incompatible material, and a second metal layer is directly formed on the upper surface of the semiconductor incompatible material. Preferably, the metal layers may be made from platinum or from aluminium. Together with the semiconductor incompatible material the two metal layers represent a sandwich like structure, which represents a capacitor.

According to a further embodiment of the invention as set forth in claim 14, the semiconductor incompatible material is a lead containing ceramics; in particular the semiconductor incompatible material is Lead Lanthanum Zirconium Titanate (PLZT). Using such kinds of dielectric materials, which exhibit a strong spontaneous electric polarization, an integrated circuit element comprising ferroelectric components may be build up.

Preferably, ferroelectric capacitors are formed in the integrated circuit element. The close encapsulation of the semiconductor incompatible material prevents a contamination within the manufacturing process. Such a contamination would be destructive in particular when heavy metal lead atoms or heavy metal lead clusters penetrate in semiconductor regions of the integrated circuit element.

According to a further embodiment of the invention as set forth in claim 15, the integrated circuit element further comprises a first semiconductor electric component and a first non-semiconductor electric component including the semiconductor incompatible material.

It has to be noted that the electronic circuit element may comprise both active electric components and/or passive electric components. According to the well-known definition of active and passive in the field of electronic components a passive component is e.g. a resistor, a capacitor, a coil or a diode. An active electric component is e.g. a transistor. Therefore, it may be possible to build up various types of electronic circuit elements within the integrated circuit element. For instance, the first semiconductor electric component may be a diode and the first non-semiconductor electric component may be a dielectric or a ferroelectric capacitor.

According to a further embodiment of the invention as set forth in claim 16, the integrated circuit element further comprises a second semiconductor electric component and/or a second non-semiconductor electric component. The second semiconductor electric component may be a silicon resistance. The second non-semiconductor electric component may be a metallic resistance. Thereby, integrated circuit elements may be build up, which circuit elements represent e.g. low-pass filter, high-pass filter and/or any other electronic circuits comprising these types of electric components formed in an integrated circuit design.

The above-mentioned need may further be met by a method for producing an integrated circuit element as set forth in claim 17. According to a third aspect of the invention the integrated circuit comprises a plurality of integrated circuit elements according to any one of the above-mentioned claims describing an integrated circuit element. The integrated circuit, which preferably may be formed directly on a wafer substrate, may be a so-called Wafer-Level-Package or Chip-Size-Package.

A high quality of integrated circuits comprising a plurality of circuit elements can be guaranteed because the encapsulating of the semiconductor incompatible material ensures that during and after the manufacturing process of the integrated circuit no contamination originates from the semiconductor incompatible material.

At this point it has to be noted that certain embodiments of the invention have been described with reference to production methods and other embodiments of the invention have been described with reference to an integrated circuit element. However, a person skilled in the art will gather from the above and the following description that, unless other notified, any combination between features of the method claims and features of the claims describing a circuit element is possible and is supposed to be disclosed with this application.

The aspects defined above and further aspects of the present invention are apparent from the examples of embodiment to be described hereinafter and are explained with reference to the examples of embodiment. The invention will be described in more detail hereinafter with reference to examples of embodiment but to which the invention is not limited.

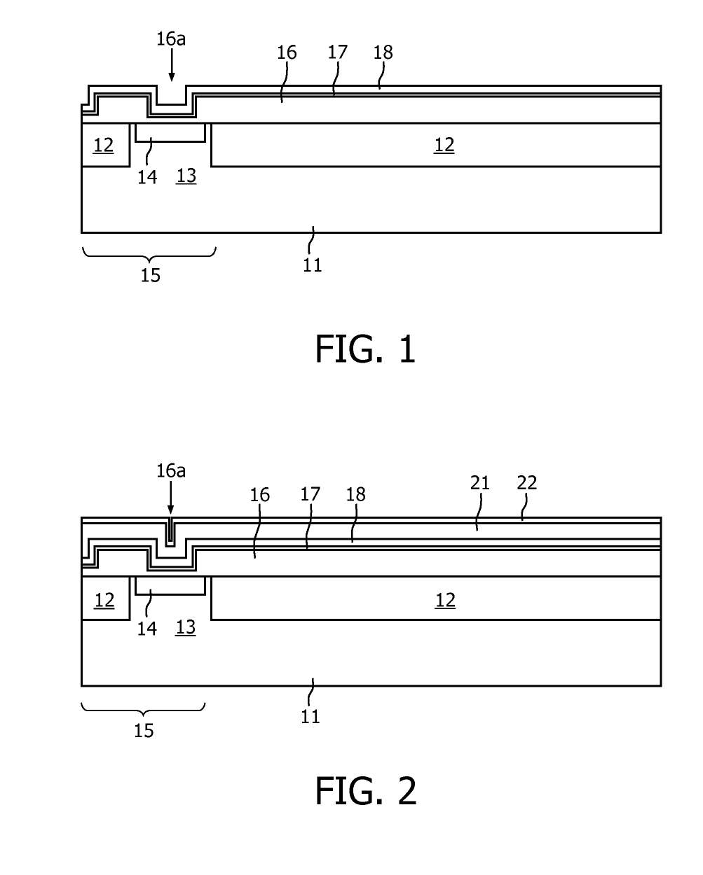

FIGS. 1 to 8 show sectional views of various process steps for building up an integrated circuit element comprising passive electric components, wherein one passive component is formed with a semiconductor incompatible material.

The illustration in the drawing is schematically. It is noted that in different drawings, similar or identical elements are provided with the same reference signs.

The description of the process for building up an integrated circuit element starts with a structure, which is schematically depicted in FIG. 1. The structure is built on a substrate 11, which is a p⁺ doped silicon substrate. The substrate 11 represents a part of a silicon wafer disk. After a completion of the integrated circuits elements the wafer might be singularized into individual circuit elements by applying appropriate techniques like wafer sawing, laser cutting etc.

On the substrate 11 there are formed two regions 12, which are deep p doped regions. Between these two regions 12 there is provided a region 13 representing a p doped region, which has been generated by an epitaxial growth procedure. Such a epitaxial growth procedure is well known in the art.

On top of the p doped region 13 and also between the two regions 12 there is formed a n doped region 14. The deep p doped region 12 located on the left side of the shown structure and the n doped region 14 form a diode 15. The diode 15 will be contacted with succeeding process steps, which will be illustrated later in this description with reference to the FIGS. 2 to 8.

The structure further comprises a neutral point clamp mask (NPC mask) 16, which is formed as a layer on top of the two deep p doped regions 12 and on top of the n doped region 14. The NPC mask 16 comprises a recess 16a. On top of the NPC mask 16 there is further provided a titan layer 17, which might be formed by means of sputtering. The titan layer has a thickness of approximately 20 nm.

As an alternative, the layer 17 might be a Titan Nitride/Titan (TiN/Ti) layer, which is capable of preventing a barrier oxidation which might occur during succeeding process steps, in particular during annealing steps.

On top of the titan layer 17 there is provided a platinum layer 18, which preferably also might be formed by means of sputtering. The platinum layer 18 has a thickness of approximately 140 nm.

It has to be pointed out that of course there are various ways which a appropriate for forming the structure shown in FIG. 1. It should be clear that a person skilled in the art of manufacturing semiconductor components and integrated circuits will be able to define an appropriate process leading to the depicted structure.

As can be seen from FIG. 2, the manufacturing process continues with the formation of a Lead Lanthanum Zirconium Titanate (PLZT) layer 21, which represents a lead containing ceramics and which exhibits strong ferroelectric properties. Therefore, PLZT is considered as to be one of the most preferable materials for building up ferroelectric capacitors.

According to the embodiment described herewith the PLZT layer 21 is formed by a sequence of a coating procedure and a curing procedure. During the curing procedure the PLZT is heated up to a temperature of approximately 700° Celsius. This sequence is carried out four to five times. After finishing this sequence a final annealing procedure follows, wherein the structure is heated up to a temperature of approximately 700° Celsius. Thereby, a stable PLZT layer 21 with a thickness of approximately 350 nm may be formed on top of the platinum layer 18.

As can be further seen from FIG. 2, the manufacturing process continues with the formation of a platinum layer 22, which preferably also might be formed by means of sputtering. The platinum layer 22 has a thickness of approximately 100 nm.

Both, the coarse of the PLZT layer 21 and the coarse of the upper platinum layer 22 follow the recess 16a formed in the NPC mask 16. Therefore, these two layers 21 and 22 make the recess 16a as to be reduced in width.

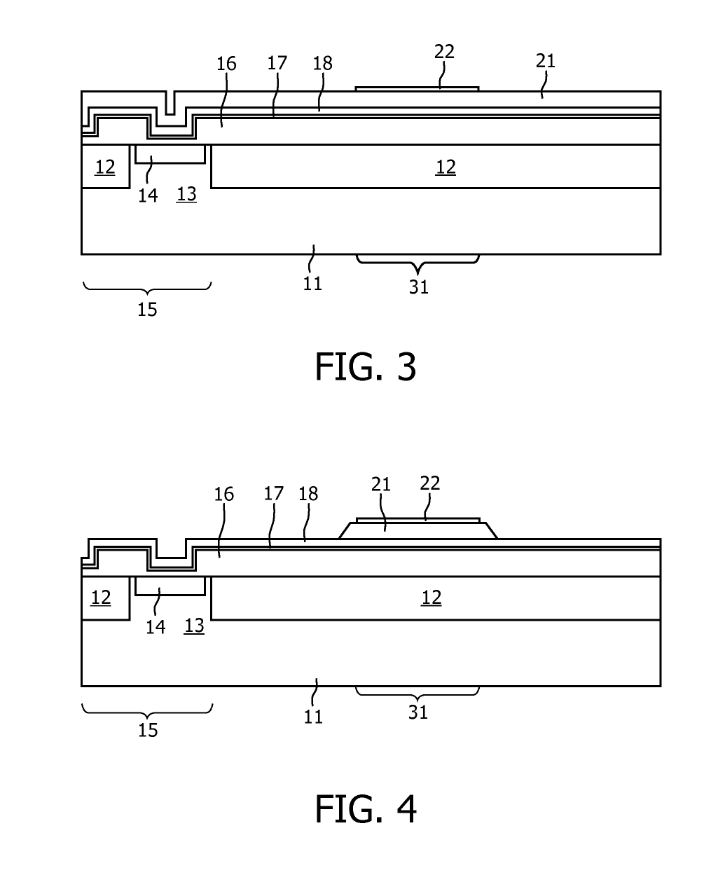

FIG. 3 illustrates the next step of the manufacturing process. Thereby, the upper platinum layer 22 is partially removed such that the platinum layer 22 remains only within a comparatively small region. Preferably, the removal is carried out by means of a plasma etch procedure by employing a PLZT mask. The parameters of the plasma etch procedure are chosen such that the material removal automatically stops when the platinum 22 has been completely removed in the corresponding regions. As a result, a ferroelectric capacitor 31, which is supposed to be formed with further process illustrated in FIGS. 4 to 8 can be made out for the first time. As one can recognize already from FIG. 3, the capacitor will develop under the platinum layer 22.

FIG. 4 illustrates how the manufacturing process of the integrated circuit element further continues. In a corresponding further process step the PLZT layer 21 is partially removed such that the PLZT material 21 remains only in a region below the remaining platinum layer 22. This removing of PLZT is preferably accomplished by means of a wet etch procedure, whereby the parameters of the procedure are selected such that no platinum material is removed neither from the upper platinum layer 22 nor from the lower platinum layer 18.

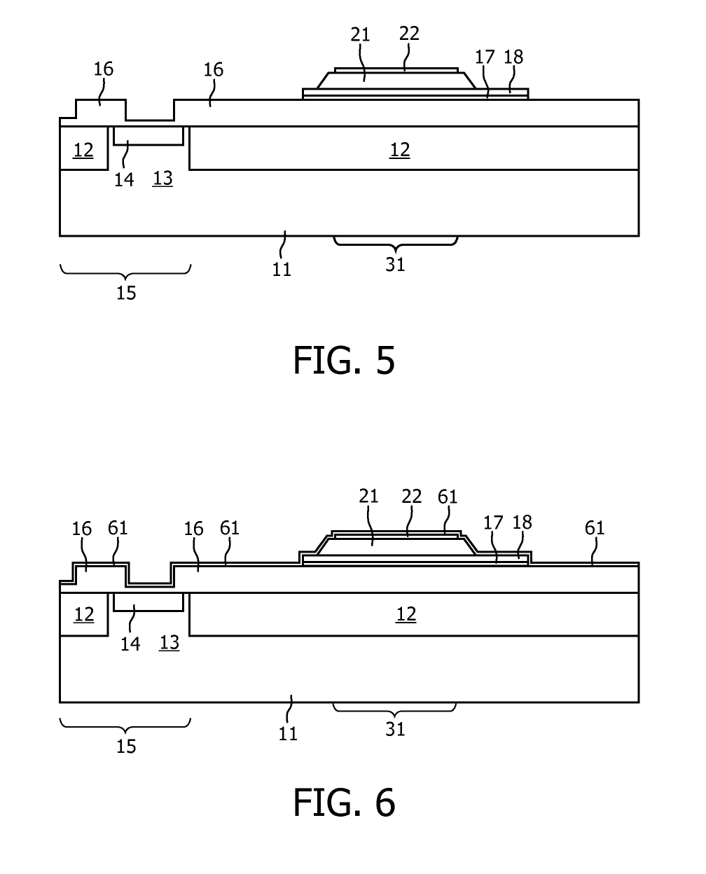

The manufacturing process of the integrated circuit element continues with a step which is illustrated in FIG. 5. Thereby, the platinum layer 18 and the titan layer 17 are partially removed preferably by means of a single removal procedure. The removal of these layers may be carried out by means of a plasma etch process whereby a bottom platinum mask is employed. The parameters of this plasma etch process are chosen such that the material removal automatically stops at SiO₂, which is the material from which the NPC mask 16 is formed.

FIG. 6 illustrates the next step of the integrated circuit element manufacturing process. Within this step an encapsulating layer 61 is formed on top of the whole structure. The encapsulating layer 61 preferably is made from nitride. According to the embodiment of the invention described here the nitride layer 61 is formed by means of a plasma nitride deposition, wherein a layer having a thickness between 100 nm and 500 nm is formed.

It has to be pointed out that the encapsulating layer 61 is formed as early as possible in order to provide for a close barrier for clusters or even for single atoms, in particular for lead atoms which might contaminate other regions of the structure which has not been completed yet. Therefore, the risk of a contamination due to particles originating from the PLZT material 21 is reduced to a minimum.

It has to be pointed out that the invention is not restricted to PLZT as the material which is selected for forming a ferroelectric component. According to embodiments of the present invention the material, which has to be encapsulated early in the integrated circuit production process, might by any material which is harmful and/or which represents a possible contamination source for a semiconductor material utilized in the direct environment of the dangerous material. Therefore, a material which is to be encapsulated might be any new material, which up to now has not been used for manufacturing integrated circuits because, in the absence of a encapsulation, the probability for unwanted contaminations of the process environment is too high.

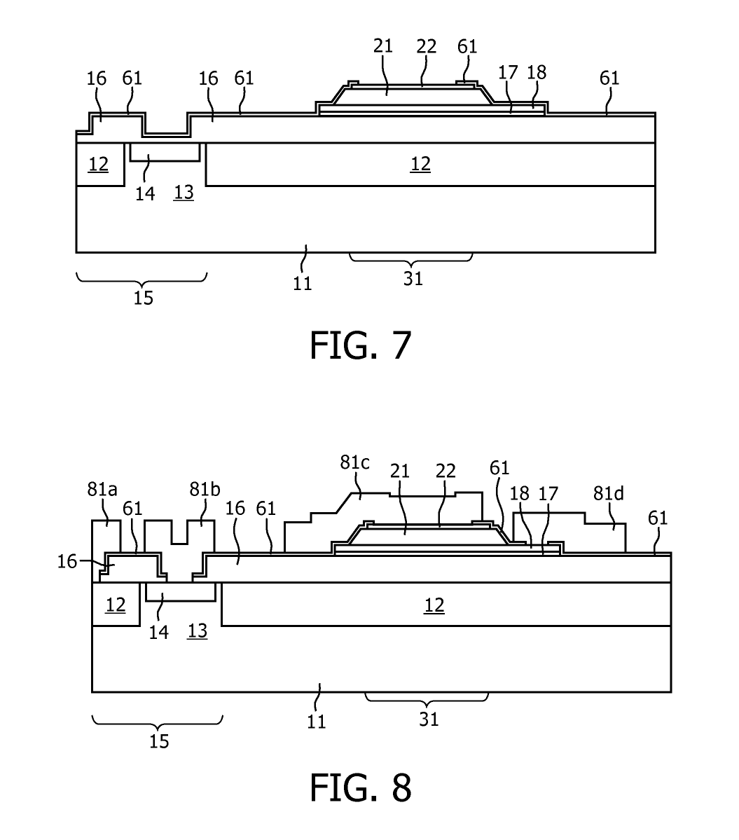

FIG. 7 illustrates the next step following the encapsulation step of the integrated circuit manufacturing process. Within this step the encapsulating layer 21 is partially removed. Preferably, the removal is carried out by means of a plasma etch process. Thereby, a so-called Contact Opening mask may be employed, which ensures that the removal of the encapsulating layer 21 is only performed in a region above the remaining upper platinum layer 22 and in regions on top of the deep p doped region 12, on top of the n doped region 14 and on top of the platinum layer 18, respectively.

It has to be pointed out that areas of removal of the encapsulating layer 21 are at least slightly smaller than the areas of the corresponding underneath located regions, respectively. This is in particular important for the removal of the encapsulating layer 21, which is carried out directly above the PLZT material 21. According to the embodiment of the invention described herewith it is very important that the PLZT material 21 in encapsulated such that absolutely no contamination may arise from the PLZT material 21.

As can be seen from FIG. 8 within a next step contact terminals are formed in order to provide for the possibility to electrically contact the components (i.e. the diode 15 and the capacitor 31) formed on the integrated circuit element. Within this step a first terminal 81a for the diode 15, a second terminal 81b for the diode, a first terminal 81c for the capacitor 31 and a second terminal 81d for the capacitor 31 are created. These terminals 81a, 81b, 81c and/or 81d are preferably made from indium (IN) by means of a IN metallization and a subsequent IN structuring process. The IN structuring process may be carried out by means of wet etching for which an appropriate mask may be used.

After the integrated circuit structure shown in FIG. 8 has been formed, there may be carried out two additional steps: A) By means of a first additional step a resistive layer, preferably a TiWN layer is coated on the top of the structure shown in FIG. 8 (not shown). Depending on the type of integrated circuit element the resistive layer is structured in an appropriate way. The structuring might be accomplished by means of a plasma etch procedure. Thereby, resistors may be formed which also represent components of the integrated circuit element. Depending on the geometry, i.e. the thickness and the area of the resistive layer the ohmic resistance may be adjusted.

As an alternative, the resistive layer may also be directly sputtered onto the upper surface of the structure shown in FIG. 8. Thereby, an appropriate mask may be employed. As has been described in the patent application WO 2005/024914, which is incorporated by reference herewith, the sputtering technique may provide for the advantage that resistor components can be built very precisely such that they comprise an exactly defined ohmic resistance.

B) By means of a second additional production step a passivation layer (not shown) may be formed in order to protect the manufactured integrated structure. The passivation layer may serve as a protection shield for the integrated circuit element against mechanical and/or chemical damages.

It should be noted that the term “comprising” does not exclude other elements or steps and the “a” or “an” does not exclude a plurality. Also elements described in association with different embodiments may be combined. It should also be noted that reference signs in the claims should not be construed as limiting the scope of the claims.

In order to recapitulate the above described embodiments of the present invention one can state:

It is described a procedure for the integration of semiconductor incompatible materials in a process family created for the production of passive electric components and active electric components formed within integrated circuits. The procedure is applicable in known techniques like bipolar, MOS or BIMOS processes for semiconductor production. The modular concept of the described procedure may combine diodes, resistors and capacitors, which components are made from different materials. The provision of an encapsulation material for a semiconductor incompatible material enables the manufacturing of integrated circuits even within a sensitive environment with respect to contaminations originating from the semiconductor incompatible material. The encapsulation is provided early within the manufacturing process such that the risk for a contamination may be reduced to a minimum.

Further, it is described an integrated circuit element and an integrated circuit comprising an encapsulated semiconductor incompatible material. The semiconductor incompatible material may be a lead containing ceramics, in particular Lead Lanthanum Zirconium Titanate (PLZT), which is used for ferroelectric capacitors and which represents a highly contaminating substance in particular for ‘heavy metal sensitive’ environments.

1. A method for producing an integrated circuit element, in particular for producing an integrated circuit which comprises both semiconductor electric components and non semiconductor electric components, the method comprising the steps of
forming a layer of a semiconductor incompatible material on a substrate,
encapsulating the semiconductor incompatible material with an encapsulating material, and
further processing the integrated circuit, wherein contact electrodes are formed in order to contact a component comprising the semiconductor incompatible material.

2. The method according to claim 1, wherein
the step of forming a layer of a semiconductor incompatible material on a substrate comprises the steps of
forming a first metal layer on the substrate and
forming the semiconductor incompatible material on the first metal layer.

3. The method according to claim 2, wherein
the step of forming a layer of a semiconductor incompatible material on a substrate further comprises the step of
forming a second metal layer on top of the semiconductor incompatible material.

4. The method according to claim 2, further comprising the step of
partially removing the semiconductor incompatible material such that at least one isolated island remains on the substrate.

5. The method according to claim 4, wherein
the at least one isolated island of semiconductor incompatible material is located on the first metal layer, wherein
the isolated island covers an area which is at least slightly smaller than the underlying area of the first metal layer and wherein
the isolated island is located within a two-dimensional region defined by the lateral edges of the first metal layer.

6. The method according to claim 3, wherein
the encapsulating material is a protection film, in particular a nitride film.

7. The method according to claim 6, further comprising the step of
partially removing the protection film.

8. The method according to claim 3, wherein
the integrated circuit includes a capacitor, which is build up from the semiconductor incompatible material located between the first metal layer and the second metal layer.

9. The method according to claim 8, wherein
the capacitor is a ferroelectric capacitor.

10. The method according to claim 9, wherein
the semiconductor incompatible material is a lead containing ceramics, in particular the semiconductor incompatible material is Lead Lanthanum Zirconium Titanate.

11. The method according to claim 10, wherein
the capacitor represents a symmetric assembly, wherein one type of dielectric layer is inserted between the first metal layer and the second metal layer.

12. An integrated circuit element, in particular an integrated circuit element being manufactured by applying a method according to claim 1, the integrated circuit element comprising
a substrate,
a semiconductor incompatible material formed on the substrate and
an encapsulating material encapsulating the semiconductor incompatible material.

13. The integrated circuit element according to claim 12, further comprising
a first metal layer formed directly on the lower surface of the semiconductor incompatible material, and
a second metal layer formed directly on the upper surface of the semiconductor incompatible material.

14. The integrated circuit element according to claim 13, wherein
the semiconductor incompatible material is a lead containing ceramics, in particular the semiconductor incompatible material is Lead Lanthanum Zirconium Titanate.

15. The integrated circuit element according to claim 12, further comprising
a first semiconductor electric component and
a first non-semiconductor electric component including the semiconductor incompatible material.

16. The integrated circuit element according to claim 15, further comprising
a second semiconductor electric component and/or
a second non-semiconductor electric component.

17. An integrated circuit, comprising
a plurality of integrated circuit elements according to claim 1.
